(19) United States
(12) Patent Application Publication
(10) Pub. No.: US 2012/0057301 A1
(43) Pub. Date: Mar. 8, 2012

(54) HEAT DISSIPATION APPARATUS AND ELECTRONIC DEVICE INCORPORATING SAME

(75) Inventor: ZEU-CHIA TAN, Tu-Cheng (TW)

(73) Assignee: HON HAI PRECISION INDUSTRY CO., LTD., Tu-Cheng (TW)

(21) Appl. No.: 12/909,806

(22) Filed: Oct. 21, 2010

(30) Foreign Application Priority Data
Sep. 3, 2010 (TW) 99129956

(51) Int. Cl. H05K 7/20; F28D 15/04

(52) U.S. Cl. 361/697; 165/104.26

(57) ABSTRACT

A heat dissipation apparatus for an electronic device includes a centrifugal fan, a fin assembly, a heat pipe and an air guiding plate. The fin assembly is disposed at an air outlet of the centrifugal fan. The heat pipe includes a condensing section thermally connected to the fin assembly and an evaporating section. The air guiding plate extends from the air outlet toward a side of the centrifugal fan, and has a first end adjacent to the air outlet and a second end far from the air outlet. When the heat dissipation apparatus is mounted in a casing, a drawing passage and an exhaust passage are defined at two lateral sides of the air guiding plate. In operation, airflow in the drawing passage is blocked by the air guiding plate to circulate past the second end of the air guiding plate and enter the exhaust passage.

### BACKGROUND

1. Technical Field

The disclosure generally relates to heat dissipation, and more particularly to a heat dissipation apparatus which can dissipate heat from two or more electronic components. 2. Description of Related Art

With the continuing development of electronic technology, processors of electronic devices such as notebook computers have become faster and faster, which causes the processors to generate more redundant heat. Heat dissipation apparatuses are traditionally disposed in the electronic devices to help transfer of the heat from the processor to the outside of the electronic device. Thus a normal, stable operating temperature of the processor is maintained.

Generally, a heat dissipation apparatus includes a heat sink and a fan. The heat sink includes a plurality of parallel fins. The heat sink is attached to the processor for absorbing heat therefrom. The fan is disposed beside or on top of the heat sink to dissipate heat transferred to the fins of the heat sink from the processor. However, in many electronic devices, some other electronic components also generate a great amount of heat. Such electronic components are typically located in a region with sluggish airflow. The heat dissipation apparatus cannot dissipate heat from these electronic components effectively.

What is needed, therefore, is a means to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead placed upon clearly illustrating the principles of the present embodiments. Moreover, in the drawings, like reference numerals designate corresponding parts throughout the several views.

FIG. 1 is an isometric, partially exploded view of an electronic device according to an exemplary embodiment of the present disclosure.

FIG. 2 is an enlarged view of some components of the electronic device of FIG. 1.

FIG. 3 is an assembled view of the electronic device of FIG. 1, but omitting a top cover thereof.

FIG. 4 is similar to FIG. 3, but viewed from a different aspect.

FIG. 5 is a top plan view of some components of the electronic device of FIG. 4, showing a field of airflow in the electronic device.

### DETAILED DESCRIPTION

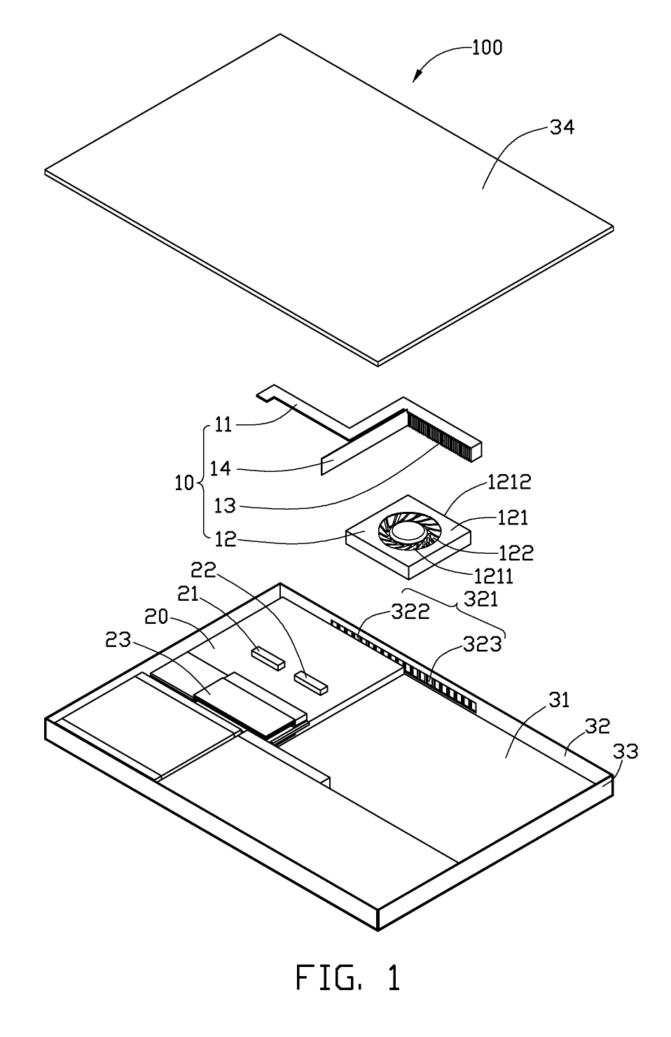

Referring to FIG. 1, an electronic device 100 according to an exemplary embodiment of the present disclosure is shown. The electronic device 100 includes a casing 30, and a circuit board 20 and a heat dissipation apparatus 10 received in the casing 30. A plurality of electronic components, such as a central processing unit (CPU) 21, a south bridge chipset 22 and a memory card 23, are mounted on the circuit board 20 and spaced from each other. The heat dissipation apparatus 10 is used for dissipating heat from the CPU 21, the south bridge chipset 22 and the memory card 23.

The casing 30 is a thin, hollow shell. The casing 30 includes a rectangular bottom plate 31, a rectangular top plate 34 opposite to the bottom plate 31, and a sidewall between the bottom plate 31 and the top plate 34. The sidewall extends up from a periphery of the bottom plate 31, and includes two opposite first side plates 32 (i.e., a front side plate 32 and a rear side plate 32) and two opposite second side plates 33. The rear side plate 32 defines a plurality of through holes 321 therein. The through holes 321 are distributed along a longitudinal direction of the rear side plate 32 and are spaced apart from each other. Some of the through holes 321 function as air intakes 322 for allowing airflow into the casing 30, and the other through holes 321 function as exhaust vents 323 for allowing airflow out of the casing 30.

The heat dissipation apparatus 10 includes a heat pipe 11, a fin assembly 13 attached on the heat pipe 11, an air guiding plate 14 locate at a side of the fin assembly 13 and fixed to the heat pipe 11, and a centrifugal fan 12.

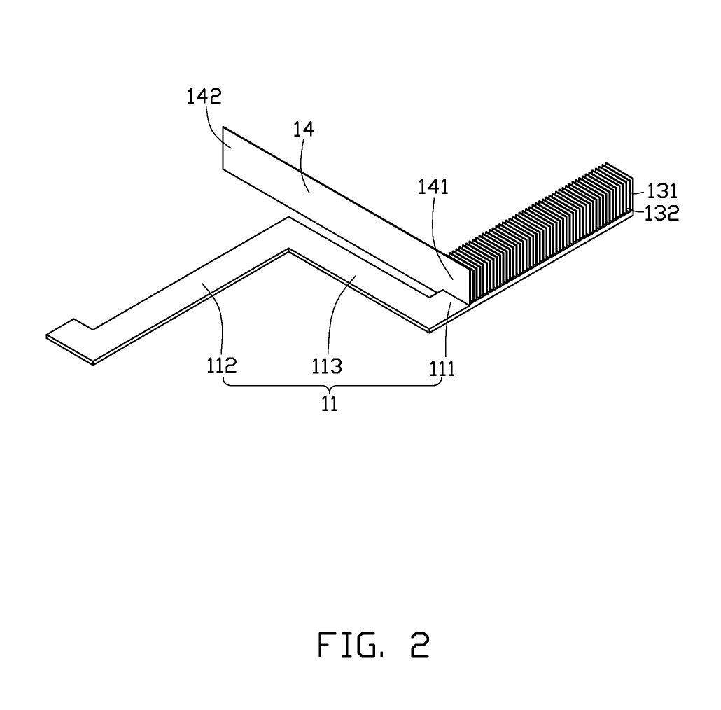

Referring also to FIG. 2, the heat pipe 11 is flattened. The heat pipe 11 includes an elongated condensing section 111, an elongated evaporating section 112, and a connecting section 113 between the condensing section 111 and the evaporating section 112. The condensing section 111 and the evaporating section 112 extend substantially perpendicularly from two opposite ends of the connecting section 113, and are located at two opposite sides of the connecting section 113. The evaporating section 112 of the heat pipe 11 is located adjacent to the second end 142 of the air guiding plate 14.

The centrifugal fan 12 includes a housing 121, and an impeller 122 rotatably mounted in the housing 121. The housing 121 defines an axial air inlet 1211 in a top side thereof and an air outlet 1212 in a lateral side thereof. A thickness of the housing 121 is smaller than that of the casing 30.

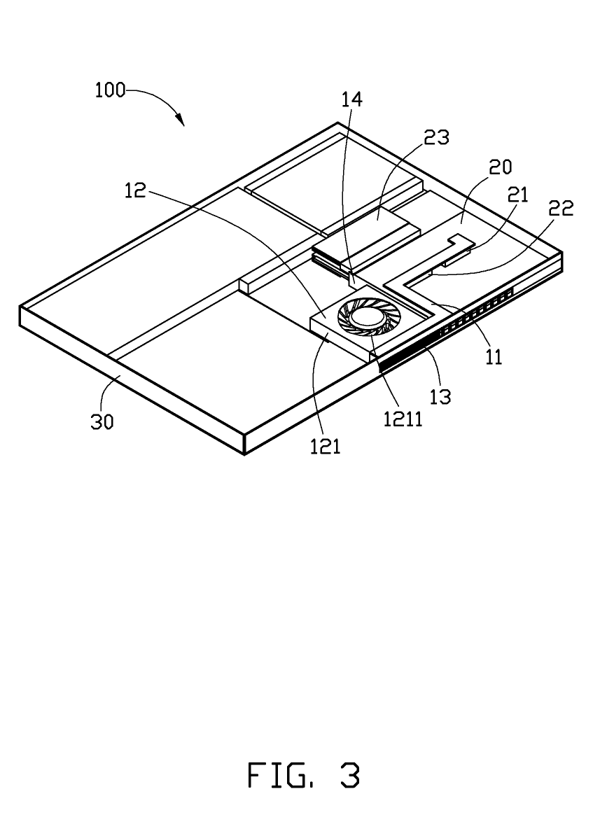

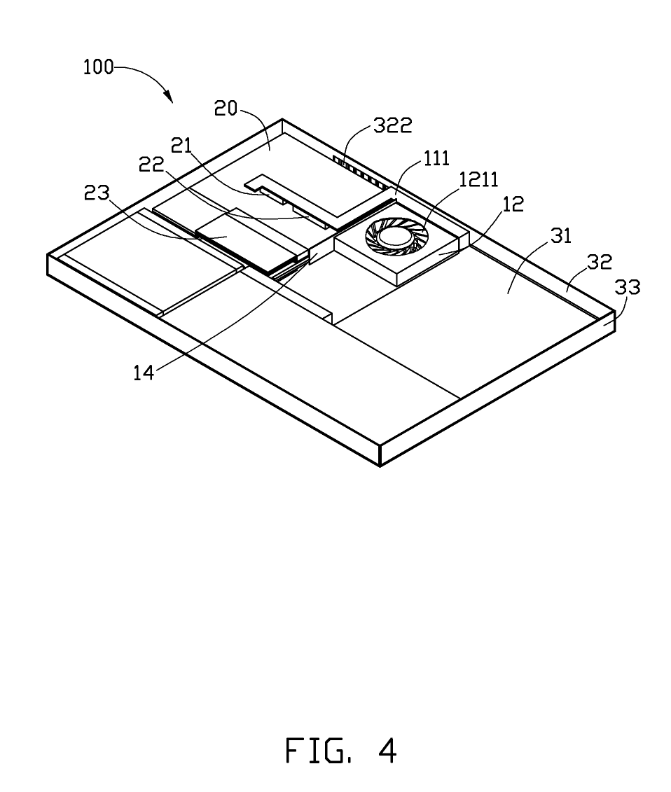

Referring also to FIGS. 3-4, the fin assembly 13 is disposed at the air outlet 1212 of the centrifugal fan 12. The condensing section 111 of the heat pipe 11 is attached on and fixed to the fin assembly 13. The fin assembly 13 includes a plurality of parallel fins 131 spaced from each other. An air channel 132 is defined between every two adjacent fins 131 (see FIG. 2).

The air guiding plate 14 is elongated, and includes a first end 141 adjacent to the air outlet 1212 of the centrifugal fan 12, and a second end 142 far from the air outlet 1212 of the centrifugal fan 12. The air guiding plate 14 is located at a side of the fin assembly 13 adjacent to the connecting section 113 of the heat pipe 11. The first end 141 of the air guiding plate 14 is coupled to the fin assembly 13 and fixed to the condensing section 111 of the heat pipe 11. The air guiding plate 14 can be formed with one outermost fin 131 of the fin assembly 13. The air guiding plate 14 extends along a longitudinal direction of the connecting section 113 of the heat pipe 11 and beyond the connecting section 113. In other words, a length of the air guiding plate 14 is longer than that of the connecting section 113 of the heat pipe 11. In this embodiment, the air guiding plate 14 is parallel to the connecting section 113 of the heat pipe 11. The second end 142 of the air guiding plate 14 extends beyond a side of the centrifugal fan 12 opposite to the air outlet 1212. A bottom edge of the air guiding plate 14 abuts against the bottom plate 31. A top edge of the air guiding plate 14 is higher than the top side of the housing 121 of the centrifugal fan 12.

The circuit board 20 is mounted on the bottom plate 31 of the casing 30 and located adjacent to the rear side plate 32 of the casing 30. A height of the circuit board 20 is lower than that of the rear side plate 32 of the casing 30. The CPU 21 and the south bridge chipset 22 are aligned with the air intakes 322 defined in the rear first side plate 32 of the casing 30. The memory card 23 is located at a front side of the CPU 21 (see FIG. 4).

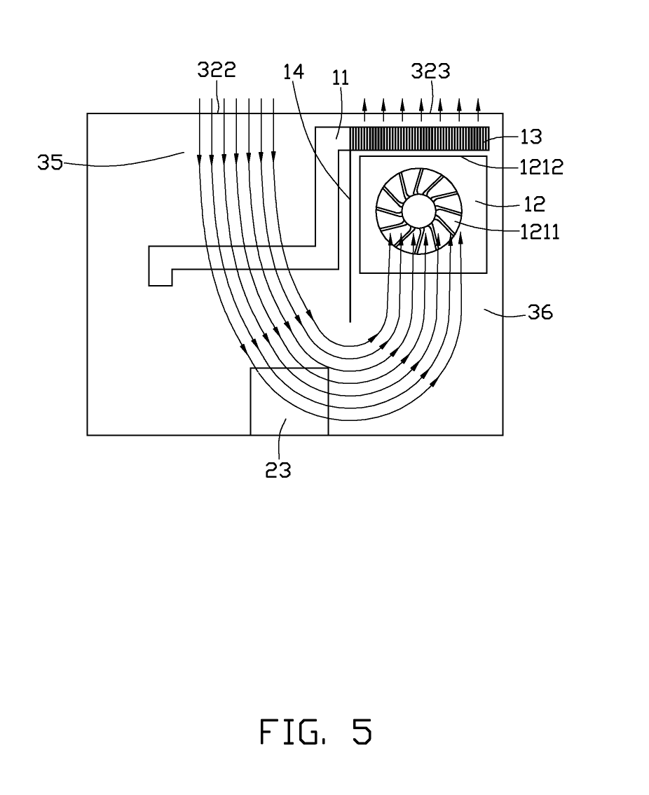

Referring also to FIG. 5, in assembly, the centrifugal fan 12 is mounted at a side of the circuit board 20, with the air outlet 1212 thereof facing the exhaust vents 323 defined in the rear first side plate 32 of the casing 30. The fin assembly 13 is disposed at the air outlet 1212 of the centrifugal fan 12, and located between the centrifugal fan 12 and the exhaust vents 323 of the casing 30. The air guiding plate 14 is disposed between the centrifugal fan 12 and the circuit board 20. The evaporating section 112 of the heat pipe 11 is thermally attached to the CPU 21 and the south bridge chipset 22. The condensing section 111 of the heat pipe 11 is fixed to the fin assembly 13 and the air guiding plate 14. The bottom edge of the air guiding plate 14 abuts against the bottom plate 31. The top edge of the air guiding plate 14 is higher than the top side of the centrifugal fan 12. In particular, when the top plate 34 is mounted to the sidewall of the casing 30, the top edge of the air guiding plate 14 abuts against the top plate 34 of the casing 30. Thus, the air guiding plate 14 divides an inner space of the casing 30 into a drawing passage 35 and an exhaust passage 36. The drawing passage 35 and the exhaust passage 36 are defined at two opposite lateral sides of the air guiding plate 14. The drawing passage 35 communicates with the exhaust passage 36 at the second end 142 of the air guiding plate 14. The CPU 21, the south bridge chipset 22, the memory card 23 and the absorbing section of the heat pipe 11 are located in the drawing passage 35. The centrifugal fan 12, the fan assembly and the condensing section 111 of the heat pipe 11 are located in the exhaust passage 36. The air intakes 322 communicate with the drawing passage 35 with an outside of the casing 30 for allowing airflow into the drawing passage 35. The exhaust vents 323 communicate with the exhaust passage 36 with the outside of the casing 30 for allowing airflow out of the casing 30.

Referring particularly to FIG. 5, in operation, air outside of the casing 30 is drawn into the drawing passage 35 by the air intakes 322 to form an airflow. The air guiding plate 14 guides the airflow to flow into the exhaust passage 36 immediately. Thus, the airflow flows along the drawing passage 35 to take away heat from the CPU 21, the south bridge chipset 22 and the memory card 23, and circulates past the second end 142 of the air guiding plate 14 to enter the exhaust passage 36. In the exhaust passage 36, air is drawn into the housing 121 of the centrifugal fan 12 by the air inlet 1211. Heat generated by the CPU 21 and the south bridge chipset 22 are transferred to the fin assembly 13 by the heat pipe 11. Airflow produced by the centrifugal fan 12 from the air outlet 1212 flows through air channel 132 of the fin assembly 13 to take away heat transferred to the fin assembly 13, and then exhausts to the outside of the casing 30 via the exhaust vents 323.

In the electronic device 100, due to the presence of the air guiding plate 14, airflow in the drawing passage 35 flows along the drawing passage 35 to the second end 142 of the air guiding plate 14, for dissipating heat of the electronic components such as the CPU 21, the south bridge chipset 22 and the memory card 23 which are located in the drawing passage 35. The air guiding plate 14 guides the airflow to a region in which the speed of the airflow is otherwise sluggish. At least one electronic component (i.e., the memory card 23) is located in such region. Thus, the heat dissipation apparatus 10 can dissipate heat from a total of two or more electronic components.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat dissipation apparatus comprising:
a centrifugal fan comprising a housing and an impeller rotatably mounted in the housing, the housing defining an air inlet and an air outlet therein;
a fin assembly disposed at the air outlet of the centrifugal fan, the fin assembly comprising a plurality of spaced fins;
a heat pipe comprising a condensing section thermally connected to the fin assembly and an evaporating section for thermally connecting with a heat source; and
an air guiding plate extending from the air outlet of the centrifugal fan toward a side of the housing of the centrifugal fan, the air guiding plate having a first end adjacent to the air outlet and a second end far from the air outlet, wherein when the heat dissipation apparatus is mounted in a casing, a drawing passage and an exhaust passage are defined at two lateral sides of the air guiding plate, the centrifugal fan and the fin assembly being located in the exhaust passage, and in operation of the heat dissipation apparatus, airflow in the drawing passage is guided by the air guiding plate to circulate past the second end of the air guiding plate and enter the exhaust passage.

2. The heat dissipation apparatus of claim 1, wherein the first end of the guiding plate is fixed to the condensing section of the heat pipe.

3. The heat dissipation apparatus of claim 1, wherein the first end of the guiding plate is coupled to the fin assembly.

4. The heat dissipation apparatus of claim 1, wherein the first end of the guiding plate is coupled to the fin assembly and fixed to the condensing section of the heat pipe.

5. The heat dissipation apparatus of claim 1, wherein the heat pipe further comprises a connecting section between the evaporating section and the condensing section, the air guiding plate being located between the fin assembly and the connecting section of the heat pipe.

6. The heat dissipation apparatus of claim 5, wherein the evaporating section of the heat pipe is located adjacent to the second end of the air guiding plate.

7. The heat dissipation apparatus of claim 6, wherein the condensing section and the evaporating section extend substantially perpendicularly from two opposite ends of the connecting section, and are located at two opposite sides of the connecting section.

8. The heat dissipation apparatus of claim 1, wherein the air guiding plate is elongated, and the second end of the air guiding plate extends beyond a side of the housing opposite to the air outlet.

9. The heat dissipation apparatus of claim 1, wherein the air inlet of centrifugal fan is defined in a top side of the housing, a top edge of the air guiding plate being higher than a top side of housing of the centrifugal fan.

10. An electronic device comprising:
a casing defining one or more air intakes and one or more exhaust vents therein;
a circuit board arranged in the casing, wherein the circuit board has a plurality of electronic component mounted thereon; and
a heat dissipation apparatus mounted in the casing, the heat dissipation comprising:
a centrifugal fan located at a side of the circuit board, the centrifugal fan comprising a housing and an impeller rotatably mounted in the housing, the housing defining an air inlet and an air outlet therein, the air outlet facing the one or more exhaust vents of the casing;
a fin assembly located between the air outlet of the centrifugal fan and the one or more exhaust vents of the casing, the fin assembly comprising a plurality of spaced fins;
a heat pipe comprising a condensing section thermally connected to the fin assembly and an evaporating section thermally connected to one of the electronic components; and
an air guiding plate extending from the air outlet of the centrifugal fan toward a side of the housing of the centrifugal fan, the air guiding plate having a first end adjacent to the air outlet and a second end far from the air outlet, the air guiding plate dividing an inner space of the casing into a drawing passage and an exhaust passage, the one or more air intakes communicating the drawing passage with an outside of the casing for allowing airflow into the drawing passage, the one or more exhaust vents communicating the exhaust passage with the outside of the casing for allowing airflow out of the casing, the electronic components being located in the drawing passage, the centrifugal fan and the fin assembly being located in the exhaust passage, wherein in operation of the heat dissipation apparatus, airflow in the drawing passage is guided by the air guiding plate to circulate past the second end of the air guiding plate and enter the exhaust passage.

11. The electronic device of claim 10, wherein the first end of the guiding plate is fixed to the condensing section of the heat pipe.

12. The electronic device of claim 10, wherein the first end of the guiding plate is coupled to the fin assembly.

13. The electronic device of claim 10, wherein the heat pipe further comprises a connecting section between the evaporating section and the condensing section, the air guiding plate being located between the fin assembly and the connecting section of the heat pipe.

14. The electronic device of claim 13, wherein the evaporating section of the heat pipe is located adjacent to the second end of the air guiding plate.

15. The electronic device of claim 14, wherein the condensing section and the evaporating section extend substantially perpendicularly from two opposite ends of the connecting section, and are located at two opposite sides of the connecting section.

16. The electronic device of claim 10, wherein the air guiding plate is elongated, and the second end of the air guiding extends beyond a side of the housing opposite to the air outlet.

17. The electronic device of claim 10, wherein the air inlet of centrifugal fan is defined in a top side of the housing, a top edge of the air guiding plate being higher than a top side of housing of the centrifugal fan.

18. The electronic device of claim 10, wherein the casing comprises a bottom plate, an top plate opposite to the bottom plate, and a sidewall between the bottom plate and the top plate, the top edge of the air guiding plate abutting against the top plate of the casing.

19. The electronic device of claim 10, wherein the one or more air intakes are located adjacent to the one or more exhaust vents.

20. The electronic device of claim 19, wherein the casing comprises a bottom plate, an top plate opposite to the bottom plate, and a sidewall between the bottom plate and the top plate, the sidewall comprising two opposite first side plates plate and two opposite second side plates, both the one or more air intakes and the one or more exhaust vents being defined in one of the first side plates.
